(19) United States
(12) Patent Application Publication
(10) Pub. No.: US 2026/0089931 A1
(43) Pub. Date: Mar. 26, 2026

(54) SEMICONDUCTOR MEMORY STRUCTURE AND METHOD FOR FORMING THE SAME

(71) Applicant: Winbond Electronics Corp., Taichung City (TW)

(72) Inventors: Noriaki IKEDA, Kaohsiung City (TW); Jiun-Sheng YANG, Taichung City (TW); Hsing-Hao CHEN, Kaohsiung City (TW)

(21) Appl. No.: 18/892,880

(22) Filed: Sep. 23, 2024

(51) Int. Cl. H10B 12/00

(52) U.S. Cl. CPC H10B 12/485; H10B 12/02; H10B 12/482

(57) ABSTRACT

A semiconductor memory structure includes a semiconductor substrate having an active region and an isolation region surrounding the active region; a cap layer disposed on the semiconductor substrate; and a plurality of bit lines disposed on the semiconductor substrate. Each of bit lines includes a first conductive pattern disposed on the semiconductor substrate; a second conductive pattern disposed on the first conductive pattern; and a dielectric pattern disposed on the second conductive pattern. A sidewall of the first conductive pattern is retracted from a sidewall of the second conductive pattern.

### BACKGROUND

### Technical Field

The present disclosure relates to semiconductor memory structure, and particularly it relates to dynamic random-access memory and methods for forming the same.

### Description of the Related Art

In recent years, dynamic random access memory (DRAM) is widely used in consumer electronic products. In order to increase the density of elements in dynamic random access memory and improve the entire performance, the fabrication technique of the current dynamic random access memory continues to work toward scaling down of the elements.

However, as the elements continue to shrink, many challenges arise. For example, in the semiconductor fabrication process, as forming bit lines, bit line contacts may be offset to the isolation region, which may cause a current leakage between the active region of the semiconductor substrate and the capacitor contact. Therefore, it still needs to improve the method for fabricating dynamic random access memory to overcome the problems caused by scaling down.

### BRIEF SUMMARY

In accordance with some embodiments of the present disclosure, a semiconductor memory device is provided. The semiconductor memory device includes a semiconductor substrate, a cap layer and a plurality of bit lines. The semiconductor substrate has an active region and an isolation region surrounding the active region. The cap layer disposed on the semiconductor substrate. Each of the bit lines includes a first conductive pattern, a second conductive pattern and a dielectric pattern. The first conductive pattern disposed on the semiconductor substrate. The second conductive pattern disposed on the first conductive pattern. The dielectric pattern disposed on the second conductive pattern. A sidewall of the first conductive pattern is retracted from a sidewall of the second conductive pattern.

In accordance with some embodiments of the present disclosure, a method for forming a semiconductor memory structure is provided. The method includes: providing a semiconductor substrate having an active region and an isolation region surrounding the active region; forming a cap layer on the semiconductor substrate; forming a plurality of bit lines on the semiconductor substrate; oxidizing a portion of each of the bit lines to form a oxidation layer; removing the oxidation layer; and forming a dielectric liner on the plurality of bit lines.

### BRIEF DESCRIPTION OF THE DRAWINGS

FIG. 1 illustrates a top view of a semiconductor memory structure according to some embodiments of the present disclosure.

FIGS. 2-6 illustrate cross-sectional views of semiconductor memory structures at various stages according to some embodiments of the present disclosure.

### DETAILED DESCRIPTION

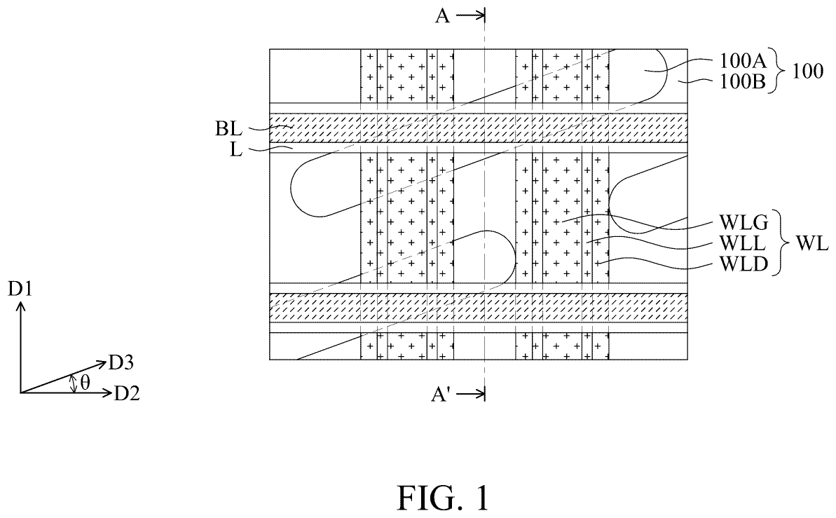

FIG. 1 illustrates a top view of a semiconductor memory structure according to some embodiments of the present disclosure. The semiconductor memory structure is a portion of dynamic random access memory array. The semiconductor memory structure includes a semiconductor substrate 100, word lines WL, bit lines BL (also denoted as 104′ in the following context) and dielectric liners L (also denoted as 108 in the following context). The semiconductor substrate 100 includes an active region 100A and an isolation region 100B surrounding the active region 100A. The word lines WL extend in the first direction D1, the bit lines BL extend in the second direction D2, and the active region 100A extends in the third direction D3. The first direction D1 is perpendicular to the second direction D2, and the third direction D3 (that is, the extending direction of the active area 100A) and the second direction D2 form an angle of about 10°-40° (e.g. 20°), so as to increase the degree of integration of the components.

The word lines WL are embedded in the semiconductor substrate 100 (not shown). The word lines WL act as a gate, which include gate dielectric layers WLD, gate liners WLL, and gate electrodes WLG extending along the first direction D1. The gate dielectric layers WLD include silicon oxide, silicon nitride, silicon oxynitride, or high-k dielectric materials or the like. The gate liners WLL include tungsten nitride (WN), titanium nitride (TiN), or tantalum nitride (TaN) or the like. The gate electrodes WLG include a conductive material, for example, doped or undoped polysilicon, metal, or metal nitride, such as tungsten (W).

It should be noted that only some of the elements of a dynamic random access memory are illustrated in FIG. 1, for brevity. Cross-sectional views in subsequent figures are illustrated along the cross-sectional line A-A′ shown in FIG. 1, which is beneficial to describe the method for forming the semiconductor memory structure.

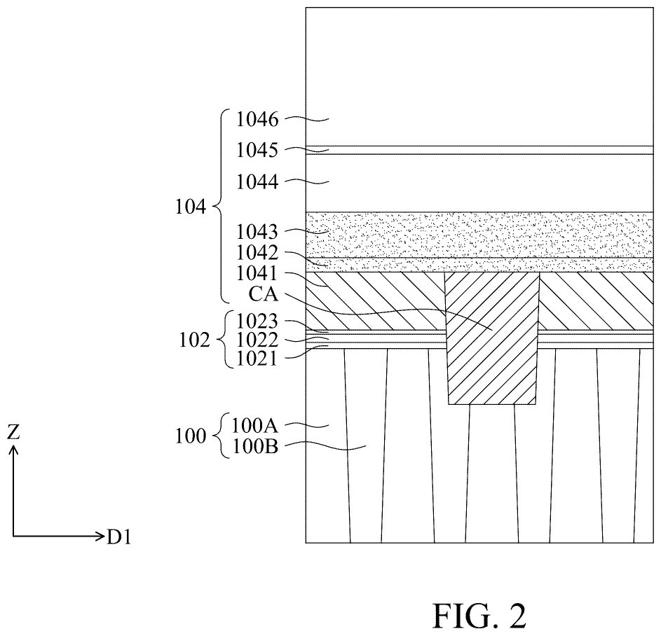

FIGS. 2-6 illustrate cross-sectional views of semiconductor memory structures at various stages according to some embodiments of the present disclosure that are taken along the cross-sectional line A-A′ (the first direction D1) in FIG. 1.

It should be noted that in cross-sectional views along cross-sectional line A-A′, the horizontal direction may be the first direction D1 and the vertical direction may be a direction Z. The first direction D1 is perpendicular to the direction Z.

As shown in FIG. 2, the semiconductor substrate 100 is provided. The semiconductor substrate 100 may be an elemental semiconductor substrate, such as a silicon substrate or a germanium substrate; a compound semiconductor substrate, such as a silicon carbide substrate or a gallium arsenide substrate, or the like. The semiconductor substrate 100 may be a semiconductor-on-insulator (SOI) substrate.

The semiconductor substrate 100 includes the active region 100A and the isolation region 100B surrounding the active region 100A. The active region 100A and the isolation region 100B are arranged alternately along the first direction D1. Isolation features (not shown) are disposed in the isolation region 100B of the semiconductor substrate 100.

Next, as shown in FIG. 2, a cap layer 102 is deposited on the semiconductor substrate 100 by a deposition process. The cap layer 102 may include a first layer 1021, a second layer 1022 and a third layer 1023.

The first layer 1021, the second layer 1022, and the third layer 1023 may include silicon oxide layers formed of tetraethylorthosilicate (TEOS), silicon nitride (SiN) or silicon oxynitride (SiON) or the like.

The deposition process may include a deposition process, such as a physical vapor deposition (PVD) process, a chemical vapor deposition (CVD) process, atomic layer deposition (ALD) process, other suitable process, or a combination of the foregoing. The aforementioned CVD process may be, for example, low pressure chemical vapor deposition (LPCVD), low temperature chemical vapor deposition (LTCVD), rapid thermal chemical vapor deposition (RTCVD), PECVD, atmospheric pressure chemical vapor deposition (APCVD) or other suitable processes.

Next, as shown in FIG. 2, a predetermined bit line layer 104 is deposited on the cap layer 102. The predetermined bit line layer 104 includes conductive layers 1041, 1042, 1043 and dielectric layers 1044, 1045. At the predetermined position, a predetermined bit line contact layer CA is embedded in the conductive layer 1041, cap layer 102, and a portion of the semiconductor substrate 100. Specifically, the opposing sidewalls of the predetermined bit line contact layer CA is embedded in the isolation region 100B. That is, the predetermined bit line contact layer CA is in the isolation region 100B, the active region 100A, and the isolation region 100B form the left sidewall to the right sidewall of the predetermined bit line contact layer CA. The conductive layer 1041 surrounds the predetermined bit line contact layer CA. The top surface of conductive layer 1041 is level with the top surface of the predetermined bit line contact layer CA.

The conductive layer 1041 and the predetermined bit line contact layer CA include doped or undoped polysilicon. The conductive layers 1042 and 1043 include metal, or metal nitride, such as tungsten (W), titanium (Ti), and titanium nitride (TiN). The dielectric layers 1044, 1045, and 1046 include nitride or oxide, such as silicon nitride or silicon oxide.

The uppermost dielectric layer 1046 is the thickest to prevent underlying film layers (such as conductive layers 1041, 1042, and 1043 and the like) from being damaged.

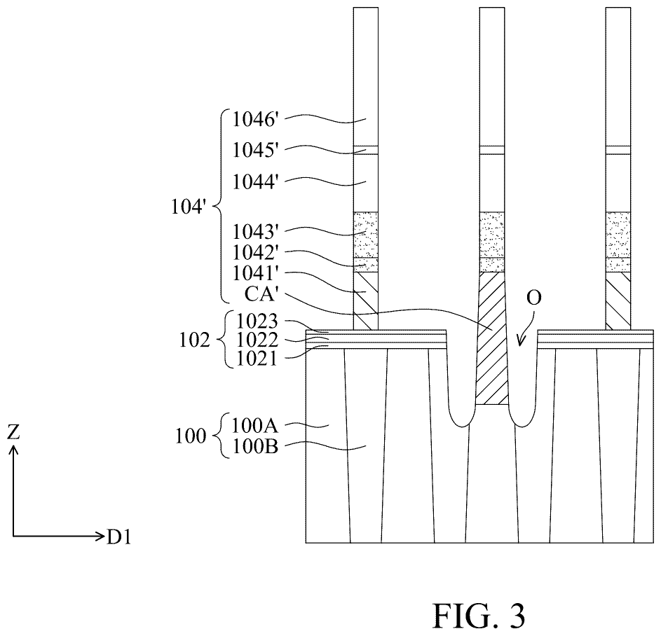

Next, as shown in FIG. 3, the predetermined bit line layer 104 is patterned by a patterning process to form bit lines 104′. Specifically, the conductive layers 1041, 1042 and 1043 and the dielectric layers 1044, 1045, and 1046 in the predetermined bit line layer 104 are etched to form the conductive patterns 1041′, 1042′and 1043′and the dielectric patterns 1044′, 1045′, and 1046′by an etching process. Also, the predetermined bit line contact layer CA in the predetermined bit line layer 104 is etched to form the bit line contact layer CA′. Openings O are also formed penetrating the cap layer 102 and contacting the semiconductor substrate 100 along the opposing sidewalls of the bit line contact layer CA′. The bottom surface of openings O is lower than the bottom surface of the bit line contact layer CA′.

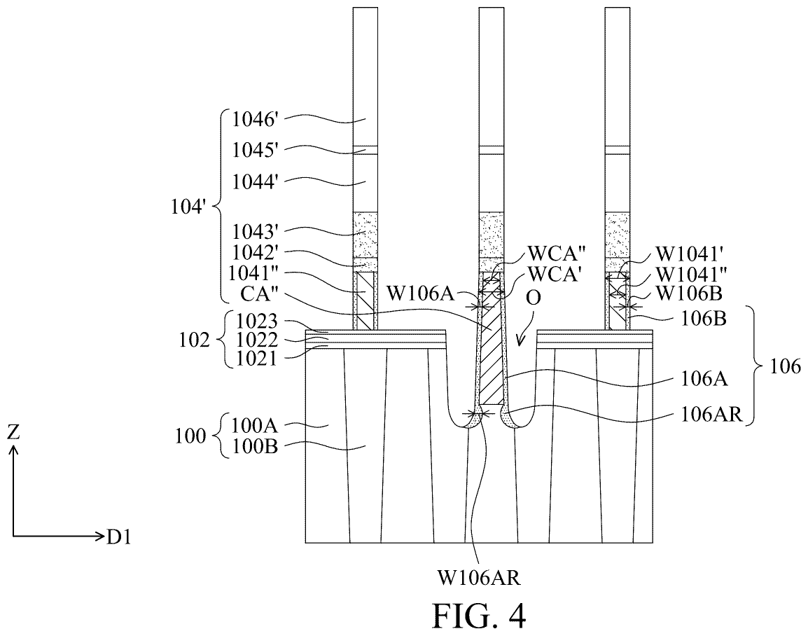

Next, as shown in FIG. 4, the bit line contact layer CA′ and the conductive layer 1041′ are oxidized by an oxidation process to form oxidation layer 106A and 106B. The remaining unoxidized bit line contact layer CA′ is denoted as a bit line contact CA″, and the remaining unoxidized conductive pattern 1041′ is denoted as a conductive pattern 1041″.

It should be noted that in this step, only materials of polysilicon will be oxidized while materials of metal or metal nitride will not be oxidized. That is, the exposed surface of the bit line contact layer CA′ and the conductive layer 1041′ are oxidized while the exposed surface of the conductive layer 1042′ is not oxidized.

Also, the exposed surface of the semiconductor substrate 100, which may be formed of silicon, may also be oxidized by an oxidation process to form oxidation layer 106AR. The oxidation of the bit line contact layer CA′ and the conductive layer 1041′ and the oxidation of semiconductor substrate 100 are performed at the same time. Thus, the oxidation layer 106A, 106B, and 106AR may be collectively referred to as the oxidation layer 106.

It should be noted that different materials result in different oxidizing rates. Specifically, the bit line contact layer CA′ and the conductive layer 1041 , which are formed of polysilicon, has different oxidizing rate from the semiconductor substrate 100, which is formed of silicon. More specifically, the ratio of the oxidizing rate of semiconductor substrate 100 and the oxidizing rate of the bit line contact layer CA′ and the conductive layer 1041′ (a portion of the bit lines 104′) is 1.1:1˜1.3:1. Therefore, the oxidation layer 106A106B will have different width from the oxidation layer 106AR. For example, the width W106AR of the oxidation 106AR is greater than the width W106A/W106B of the oxidation layer 106A/106B. Specifically, the ratio of the width W106AR and the width W106A/W106B is about 1˜1.3 or 1.1˜1.25.

The ratio of the width W106B of the oxidation layer 106B and the width W1041′ of the conductive pattern 1041′ is 1:15˜2:15. The conductive layer 1041′ has substantially same width from top to bottom. It should be noted that the sum of the width W1041″ of the conductive pattern 1041″ and the twice of the width W106B of the oxidation layer 106B is equal to the width W1041′ of the conductive pattern 1041′.

The ratio of the width W106A of the oxidation layer 106A and the width WCA′ of the bit line contact layer CA′ is 1:15˜2:15. The bit line contact layer CA′ has tapered shaped, which is wider from top to bottom. Thus, the bit line contact layer CA′ has the narrower top width than the bottom width. It should be noted that the sum of the width WCA″ of the bit line contact CA″ and the twice of the width W106A of the oxidation layer 106A is equal to the width WCA′ of the bit line contact layer CA′.

The oxidation process may include thermal oxidation, radical oxidation or other suitable processes.

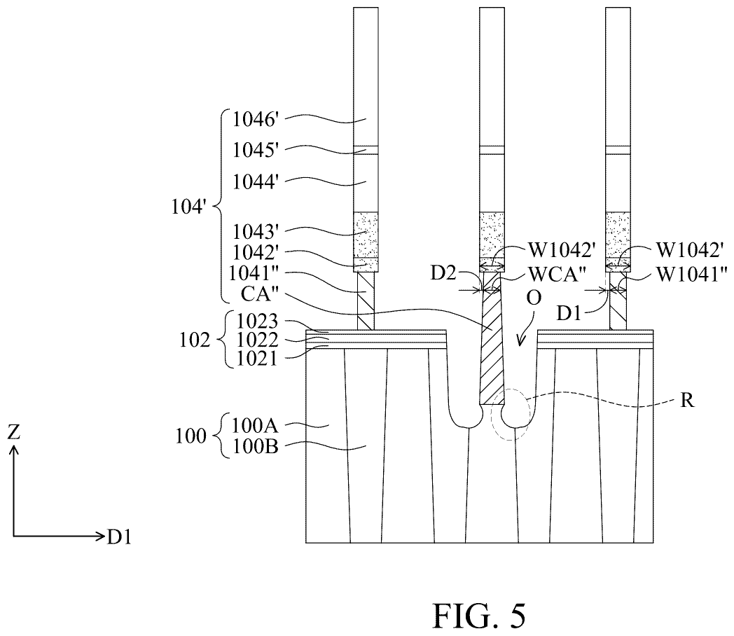

Next, as shown in FIG. 5, the oxidation layer 106 is removed. Here, the remaining bit line contact layer CA′ is denoted as the bit line contact CA″, and the remaining conductive pattern 1041′ is denoted as the conductive pattern 1041″. Specifically, the conductive pattern 1041″ in the isolation region 100B is disposed on the cap layer 102. The bit line contact CA″ in the active region 100A penetrates through the cap layer 102 and contacts the semiconductor substrate 100.

The oxidation 106AR results in recesses R in FIG. 5. The recesses R are formed under the opposing sides of the conductive pattern CA″ in the active region 100A. Also, the oxidation layer 106A and 106B affects the shape of the bit lines 104′. Specifically, the sidewall of the bit line contact CA″ and/or the sidewall of the conductive pattern 1041″ is retracted from the sidewall of the conductive pattern 1042′.

In FIG. 5, the width W1042′ of the conductive pattern 1042′ is wider than the width WCA″ of the bit line contact CA″. Also, the width W1042′ of the conductive pattern 1042′ is greater than the width W1041″ of the conductive pattern 1041″. Specifically, there is a distance D1 between the sidewall of the conductive pattern 1041″ and the sidewall of the conductive pattern 1042′. Since the conductive pattern 1041″ is substantially straight, the distance D1 may have substantially the same value from the top to the bottom of the conductive pattern 1041″.

There is a distance D2 between the sidewall of the bit line contact CA″ and the sidewall of the conductive pattern 1042′. Since the bit line contact CA″ is taper shaped, the distance D2 may be maximum value at the top of the bit line contact CA″. That is, the distance D2 may vary from the top to the bottom of the bit line contact CA′.

The distance D1 and the distance D2 are substantially the same, for example, at the top of the bit line contact CA″ and at the top of the conductive pattern 1041″.

Since the recesses R widen and deepen the openings O, a portion of the semiconductor substrate 100 under the bit line contact layer CA″ is thinner than before, and shows a necked shaped.

As the oxidation layer 106 is formed and then removed, thinner bit line contact layer CA″ is obtained and the recesses R is formed, thereby avoiding current leakage between the active region of the semiconductor substrate 100, the bit lines 104′ and the subsequently formed capacitor contact (not shown).

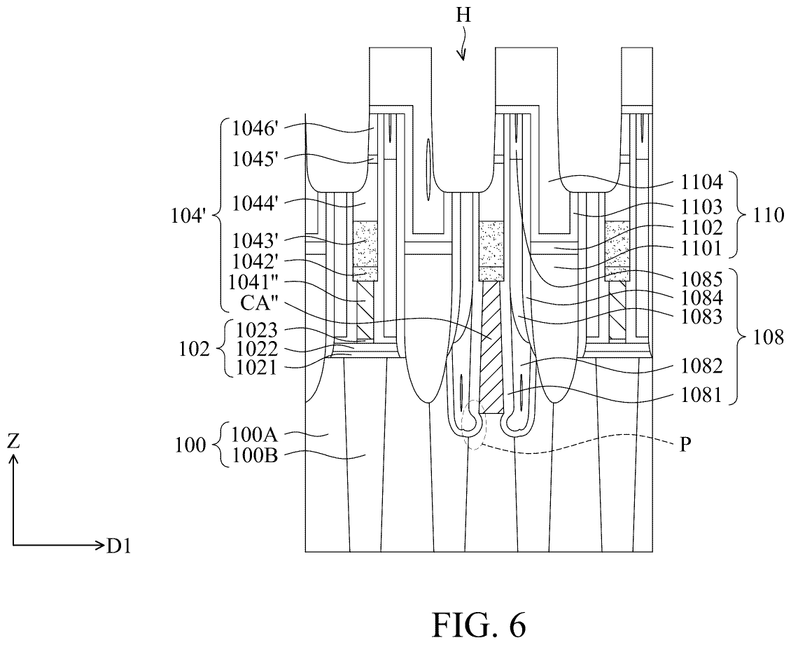

Next, as shown in FIG. 6, a dielectric liner 108 is formed. The dielectric liner 108 extends along opposing sides of the bit line contact CA″. The dielectric liner 108 contacts a bottom of the conductive pattern 1042′.

It should be noted that the dielectric liner 108 is also formed in the recesses R, which results in forming protrusions P. The protrusions P extend under the bit line contact CA″, but does not contact each other. The protrusions P contact the semiconductor substrate 100. Each of the protrusions P is spaced apart from the bottom of the bit line contact CA″ by the semiconductor substrate 100.

The dielectric liner 108 may be a single-layered structure, or a multiple-layered structure, such as a nitride-oxide-nitride structure. In the embodiment of FIG. 6, the dielectric liner 108 may include nitride layers 1081, 1082, 1084, and 1085 and oxide layer 1083 sandwiched therebetween. For example, nitride layers 1081, 1082, 1084, and 1085 may be silicon nitride and the oxide layer 1083 may be silicon oxide.

Next, as shown in FIG. 6, a plurality of capacitor contacts 110 are formed. Each of the capacitor contacts 110 is disposed between each two of the bit lines 104′. In the embodiment of FIG. 6, each of the capacitor contacts 110 may include a semiconductor layer 1101, a silicide layer 1102, an adhesive layer 1103, and a metal plug 1104. The silicide layer 1102 is formed between the semiconductor layer 1101 and the metal plug 1104 to reduce the contact resistance therebetween. The adhesive layer 1103 is formed on the silicide layer 1102 and on the dielectric liner 108 to increase the adhesion between the silicide layer 1102 and the metal plug 1104.

The semiconductor layer 1101 may be formed of polysilicon. The silicide layer 1102 may be formed of cobalt silicon (CoSi). The adhesive layer 1103 may be formed of titanium (Ti) or titanium nitride (TiN) or the like. The metal plug 1104 may be formed of tungsten (W).

The formation of the dielectric liner 108 and the plurality of capacitor contacts 110 may include the deposition process and the patterning process similar to the above, and thus are not repeated here again.

Next, as shown in FIG. 6, holes H are formed. That is, a portion of the dielectric liner 108 and a portion of the capacitor contact are etched to form the holes H. It should be understood that after the holes H are formed, additional elements, such as landing pads, capacitors, or the like, may still be formed to complete the formation of memory device (such as dynamic random access memory).

In summary, before the dielectric liner is formed, the oxidation process is performed to shrink the width of the bit line contact. In addition, due to different oxidizing rate of the polysilicon (the bit line contact or the conductive pattern) and silicon, oxidation layers formed on them have different widths. As the oxidizing rate of the silicon is higher, the recesses are formed at the semiconductor substrate after the oxidation layer is removed. Therefore, current leakage between the active region of the semiconductor substrate, the bit lines and the capacitor contact may be avoided even if the isolation region is offset formed. Therefore, the reliability and manufacturing yield of the semiconductor memory device are improved.

Although the present invention is disclosed in the foregoing embodiments, it is not intended to limit the present invention. Those with ordinary skill in the technical field to which the present invention pertains can make some changes and modifications without departing from the spirit and scope of the present invention. Thus, the scope of protection of the present invention shall be subject to those defined by the attached patent scope.

What is claimed is:

1. A semiconductor memory device, comprising:
a semiconductor substrate having an active region and an isolation region surrounding the active region;
a cap layer disposed on the semiconductor substrate; and
a plurality of bit lines disposed on the semiconductor substrate, wherein each of the bit lines comprises:
a first conductive pattern disposed on the semiconductor substrate;
a second conductive pattern disposed on the first conductive pattern; and
a dielectric pattern disposed on the second conductive pattern, wherein a sidewall of the first conductive pattern is retracted from a sidewall of the second conductive pattern.

2. The semiconductor memory device as claimed in claim 1, wherein a width of the first conductive pattern is less than a width of the second conductive pattern.

3. The semiconductor memory device as claimed in claim 1, wherein there is a distance between a sidewall of the first conductive pattern and a sidewall of the second conductive pattern.

4. The semiconductor memory device as claimed in claim 1, wherein the first conductive pattern of each of the bit lines in the isolation region is disposed on the cap layer.

5. The semiconductor memory device as claimed in claim 1, wherein the first conductive pattern of each of the bit lines in the active region penetrates through the cap layer and contacts the semiconductor substrate.

6. The semiconductor memory device as claimed in claim 5, further comprising a dielectric liner disposed along opposing sides of the first conductive pattern.

7. The semiconductor memory device as claimed in claim 6, wherein the dielectric liner has a protrusion, which further extends under the first conductive pattern.

8. The semiconductor memory device as claimed in claim 7, wherein the protrusion contacts the semiconductor substrate.

9. The semiconductor memory device as claimed in claim 7, wherein the protrusion is spaced apart from a bottom of the first conductive pattern disposed on the semiconductor substrate.

10. The semiconductor memory device as claimed in claim 1, further comprising a plurality of capacitor contacts, wherein each of the capacitor contact is disposed between each two of the bit lines.

11. A method for forming a semiconductor memory structure, comprising:
providing a semiconductor substrate having an active region and an isolation region surrounding the active region;
forming a cap layer on the semiconductor substrate;
forming a plurality of bit lines on the semiconductor substrate;
oxidizing a portion of each of the bit lines to form an oxidation layer;
removing the oxidation layer; and
forming a dielectric liner on the plurality of bit lines.

12. The method as claimed in claim 11, wherein each of the plurality of bit lines comprises:
a first conductive pattern on the semiconductor substrate;
a second conductive pattern on the first conductive pattern; and
a dielectric pattern on the second conductive pattern,
wherein oxidizing the portion of each of the bit lines comprises oxidizing side surfaces of the first conductive pattern without oxidizing side surfaces of the second pattern.

13. The method as claimed in claim 12, wherein the dielectric liner 108 contacts a bottom of the second conductive pattern.

14. The method as claimed in claim 11, further comprising oxidizing an exposed surface of the semiconductor substrate, wherein the oxidizing an exposed surface of the semiconductor substrate and oxidizing the portion of each of the bit lines are performed at the same time.

15. The method as claimed in claim 14, wherein a ratio of a oxidizing rate of an exposed surface of the semiconductor substrate and a oxidizing rate of the portion of each of the bit lines is 1.1:1˜1.3:1.

16. The method as claimed in claim 14, wherein removing the oxidation layer comprises forming recesses under the opposing sides of the first conductive pattern in the active region.

17. The method as claimed in claim 16, wherein the dielectric liner is further formed in the recess.

18. The method as claimed in claim 11, wherein a ratio of a width of the oxidation layer and a width of the second conductive pattern is 1:15˜2:15.

19. The method as claimed in claim 10, wherein forming a plurality of bit lines on the semiconductor substrate comprises:
depositing a predetermined bit line layer on the cap layer; and
patterning the predetermined bit line layer to form the plurality of bit lines.

20. The method as claimed in claim 19, wherein forming a plurality of bit lines on the semiconductor substrate further comprises:
forming a plurality of openings penetrating the cap layer and contacting the semiconductor substrate along opposing sides of the bit lines in the active region.
